(19) United States
(12) Patent Application Publication
(10) Pub. No.: US 2025/0322891 A1
(43) Pub. Date: Oct. 16, 2025

(54) MEMORY SYSTEMS, METHODS OF CONTROLLING THEREOF, AND READABLE STORAGE MEDIUMS

(71) Applicant: YANGTZE MEMORY TECHNOLOGIES CO., LTD., Wuhan (CN)

(72) Inventor: Teng ZHOU, Wuhan (CN)

(21) Appl. No.: 18/822,764

(22) Filed: Sep. 3, 2024

(30) Foreign Application Priority Data
Apr. 15, 2024 (CN) 2024104518028

(51) Int. Cl. G11C 16/34; G06F 3/06; G06F 11/10; G11C 16/04; G11C 16/26

(52) U.S. Cl. CPC G11C 16/3404; G06F 3/0619; G06F 3/0659; G06F 3/0688; G06F 11/1096; G11C 16/0483; G11C 16/26

(57) ABSTRACT

Memory systems and methods of controlling thereof are disclosed. An example memory system includes a memory device and a memory controller. The memory device includes memory cells each being configured to be in one of data states. The memory controller is configured to: control the memory device to perform a single level read operation; in response to a first count of memory cells each having a threshold voltage less than a default read voltage being less than a first threshold, determine that an optimal read voltage has a positive offset relative to the default read voltage; and in response to the first count of memory cells each having a threshold voltage less than the default read voltage being greater than a second threshold larger than the first threshold, determine that the optimal read voltage has a negative offset relative to the default read voltage.

### CROSS-REFERENCE TO RELATED APPLICATIONS

The present application claims priority to Chinese Patent Application No. 2024104518028, which was filed Apr. 15, 2024, and is hereby incorporated herein by reference in its entirety.

### TECHNICAL FIELD

Examples of the present disclosure relate to the field of semiconductor technology, and in particular, to memory systems, methods of controlling a memory system, and readable storage mediums.

### BACKGROUND

A memory device is a storage device used to save information in modern information technology. Some semiconductor memories, such as a non-volatile memory, gradually become mainstream products in the memory market due to their high storage density, controllable production cost, suitable program and erase speeds, and retention property. However, with the increasingly high requirements for the storage device, there is still much room for improvements in the memory device and a system thereof.

### SUMMARY

According to some aspects of examples of the present disclosure, a memory system is provided, comprising: a memory device comprising a plurality of or multiple memory cells, wherein each of the memory cells is configured to be in one of a plurality of or multiple data states; and a memory controller coupled with the memory device and configured to: control the memory device to perform a single level read operation; in response to a first count of memory cells each having a threshold voltage less than a default read voltage being less than a first threshold, determine that an optimal read voltage has a positive offset relative to the default read voltage; and in response to the first count of memory cells each having a threshold voltage less than the default read voltage being greater than a second threshold, determine that the optimal read voltage has a negative offset relative to the default read voltage, wherein the first threshold is less than the second threshold, wherein a first intermediate voltage is a voltage corresponding to the maximum memory cell count in a first threshold voltage distribution corresponding to memory cells in a first data state among the memory cells; a second intermediate voltage is a voltage corresponding to the maximum memory cell count in a second threshold voltage distribution corresponding to memory cells in a second data state among the memory cells; the first data state and the second data state are two adjacent data states among the data states; the first threshold is a count of memory cells each having a threshold voltage less than a first voltage in threshold voltage distributions of the data states; the second threshold is a count of memory cells each having a threshold voltage less than a second voltage in the threshold voltage distributions of the data states; the first voltage is less than the second voltage, and the first voltage and the second voltage are both between the first intermediate voltage and the second intermediate voltage.

In some examples, the memory controller is further configured to: send a first operation command to the memory device, wherein the memory device is configured to: enable a single level read operation mode in response to the first operation command.

In some examples, the first voltage is a voltage in the first threshold voltage distribution, and the second voltage is a voltage in the second threshold voltage distribution.

In some examples, the memory controller is further configured to: stop offsetting the default read voltage in response to one of the following conditions being met: the first count is greater than the first threshold and less than the second threshold; the first count is equal to the first threshold; and the first count is equal to the second threshold.

In some examples, the memory device is further configured to: acquire the first count according to a result of a read operation, wherein the memory controller is configured to: compare the first count acquired by the memory device with the first threshold; and/or compare the first count acquired by the memory device with the second threshold; and according to a result of the comparison, determine that the optimal read voltage has a positive offset relative to the default read voltage, or the optimal read voltage has a negative offset relative to the default read voltage.

In some examples, the memory controller is further configured to: acquire a result of a read operation performed by the memory device on the memory cells; and acquire the first count according to the result of the read operation.

In some examples, the memory controller is further configured to: before determining an offset direction of the optimal read voltage relative to the default read voltage, control the memory device to perform a read operation using the default read voltage; and in response to a read failure of the memory device, determine that the optimal read voltage has a positive offset or a negative offset relative to the default read voltage.

In some examples, the memory controller is further configured to: determine the optimal read voltage according to the default read voltage after being offset, and control the memory device to perform a read operation using the optimal read voltage; in response to first failure information of the memory device, perform a read retry operation for at least one time, and perform a hard bit decode operation on data obtained after the read retry operation is performed each time, wherein the first failure information is to indicate a read failure of the read operation performed using the optimal read voltage; perform a soft bit decode operation for at least one time in response to a failure of the hard bit decode operation; and perform a redundant array of independent disks (RAID) data recovery operation in response to a failure of the soft bit decode operation.

In some examples, the memory controller is further configured to: control the memory device to perform a read operation using the default read voltage; in response to second failure information of the memory device, perform a read retry operation for at least one time, and perform a hard bit decode operation on data obtained after the read retry operation is performed each time, wherein the second failure information is to indicate a read failure of the read operation performed using the default read voltage; in response to a failure of the hard bit decode operation, determine the optimal read voltage according to an offset to the default read voltage, and perform the read operation using the optimal read voltage; and perform a redundant array of independent disks (RAID) data recovery operation in response to a read failure using the optimal read voltage.

In some examples, the data states are read through a plurality of or multiple read voltages, the optimal read voltage determined according to the first threshold voltage distribution and the second threshold voltage distribution is a first optimal read voltage, the first optimal read voltage has an offset relative to a first default read voltage, and the memory controller is configured to: determine that offset directions of at least part of other optimal read voltages relative to corresponding default read voltages are the same as an offset direction of the first optimal read voltage.

In some examples, the read voltages are divided into a plurality of or multiple intervals, each interval comprises one read voltage or a plurality of or multiple adjacent read voltages, and the optimal read voltage for each interval has the same offset direction relative to the corresponding default read voltage, wherein the memory controller is further configured to: determine that an offset direction of the optimal read voltage in another interval is different from the offset direction of the first optimal read voltage.

According to some aspects of examples of the present disclosure, a method of controlling a memory system is provided, comprising: performing a single level read operation on a plurality of or multiple memory cells using a default read voltage, wherein each of the memory cells is configured to be in one of a plurality of or multiple data states; in response to a first count of memory cells each having a threshold voltage less than the default read voltage being less than a first threshold, determining that an optimal read voltage has a positive offset relative to the default read voltage; and in response to the first count of memory cells each having a threshold voltage less than the default read voltage being greater than a second threshold, determining that the optimal read voltage has a negative offset relative to the default read voltage, wherein the first threshold is less than the second threshold; wherein a first intermediate voltage is a voltage corresponding to the maximum memory cell count in a first threshold voltage distribution corresponding to memory cells in a first data state among the memory cells; a second intermediate voltage is a voltage corresponding to the maximum memory cell count in a second threshold voltage distribution corresponding to memory cells in a second data state among the memory cells; the first data state and the second data state are two adjacent data states among the data states; the first threshold is a count of memory cells each having a threshold voltage less than a first voltage in threshold voltage distributions of the data states; the second threshold is a count of memory cells each having a threshold voltage less than a second voltage in the threshold voltage distributions of the data states; the first voltage is less than the second voltage, and the first voltage and the second voltage are both between the first intermediate voltage and the second intermediate voltage.

In some examples, the method comprises: sending, by a memory controller, a first operation command to a memory device; and enabling, by the memory device, a single level read operation mode in response to the first operation command.

In some examples, the first voltage is a voltage in the first threshold voltage distribution, and the second voltage is a voltage in the second threshold voltage distribution.

In some examples, the method further comprises: stopping offsetting the default read voltage in response to one of the following conditions being met: the first count is greater than the first threshold and less than the second threshold; the first count is equal to the first threshold; and the first count is equal to the second threshold.

In some examples, the method further comprises: acquiring the first count according to a result of a read operation.

In some examples, the method further comprises: before determining an offset direction of the optimal read voltage relative to the default read voltage, performing a read operation using the default read voltage; and in response to a read failure, determining that the optimal read voltage has a positive offset or a negative offset relative to the default read voltage.

In some examples, the method further comprises: determining the optimal read voltage according to the default read voltage after being offset, and controlling the memory device to perform a read operation using the optimal read voltage; in response to first failure information, performing a read retry operation for at least one time, and performing a hard bit decode operation on data obtained after the read retry operation is performed each time, wherein the first failure information is to indicate a read failure of the read operation performed using the optimal read voltage; performing a soft bit decode operation for at least one time in response to a failure of the hard bit decode operation; and performing a redundant array of independent disks (RAID) data recovery operation in response to a failure of the soft bit decode operation.

In some examples, the method further comprises: performing a read operation using the default read voltage; in response to second failure information, performing a read retry operation for at least one time, and performing a hard bit decode operation on data obtained after the read retry operation is performed each time, wherein the second failure information is to indicate a read failure of the read operation performed using the default read voltage; in response to a failure of the hard bit decode operation, determining the optimal read voltage according to an offset to the default read voltage, and performing the read operation using the optimal read voltage; and performing a redundant array of independent disks (RAID) data recovery operation in response to a read failure using the optimal read voltage.

In some examples, the data states are read through a plurality of or multiple read voltages, the optimal read voltage determined according to the first threshold voltage distribution and the second threshold voltage distribution is a first optimal read voltage, the first optimal read voltage has an offset relative to a first default read voltage, and the method further comprises: determining that offset directions of at least part of other optimal read voltages relative to corresponding default read voltages are the same as an offset direction of the first optimal read voltage.

In some examples, the read voltages are divided into a plurality of or multiple intervals, each interval comprises one read voltage or a plurality of or multiple adjacent read voltages, and the optimal read voltage for each interval has the same offset direction relative to the corresponding default read voltage, wherein the method further comprises: determining that an offset direction of the optimal read voltage in another interval is different from the offset direction of the first optimal read voltage.

According to some aspects of examples of the present disclosure, there is provided a readable storage medium storing a computer program which, when executed, implements the method.

### BRIEF DESCRIPTION OF THE DRAWINGS

FIG. 1 is a schematic diagram illustrating an example system according to examples of the present disclosure;

FIG. 2A is a schematic diagram illustrating an example memory card according to examples of the present disclosure;

FIG. 2B is a schematic diagram illustrating an example solid state drive according to examples of the present disclosure;

FIG. 3 is a schematic diagram illustrating an example memory device according to examples of the present disclosure;

FIG. 4 is a schematic diagram illustrating an example cross section of a memory cell array according to examples of the present disclosure;

FIG. 5 is a schematic diagram illustrating another example memory device according to examples of the present disclosure;

FIG. 6 is a schematic diagram illustrating an example memory system according to examples of the present disclosure;

FIG. 7 is a schematic flow diagram illustrating an example operation according to examples of the present disclosure;

FIG. 8 to FIG. 12 are schematic diagrams illustrating example read voltage offsets according to examples of the present disclosure;

FIG. 13 is a schematic flow diagram illustrating another example operation according to examples of the present disclosure; and

FIG. 14 is a schematic flow diagram of a method of controlling a memory system according to examples of the present disclosure.

### DETAILED DESCRIPTION

Examples disclosed in the present disclosure will be described in more detail below with reference to the accompanying drawings. Although examples of the present disclosure are shown in the drawings, it should be understood that the present disclosure may be implemented in various ways and should not be limited to the DETAILED DESCRIPTION set forth herein. Rather, these examples are provided so that the present disclosure can be more thoroughly understood and the scope of the present disclosure can be fully conveyed to those skilled in the art.

In the following description, numerous specific details are given in order to provide a more thorough understanding of the present disclosure. It will be apparent, however, to one skilled in the art that the present disclosure may be practiced without one or more of these details. In other examples, some technical features well-known in the art are not described to avoid confusion with the present disclosure; that is, not all features of the actual example are described here, and well-known functions and structures are not described in detail.

It will be understood that when an element or layer is referred to as being “on,” “adjacent to,” “connected to” or “coupled to” other elements or layers, it can be directly on, adjacent to, connected to, or coupled to other elements or layers, or intervening elements or layers may be present. In contrast, when an element is referred to as being “directly on,” “directly adjacent to,” “directly connected to” or “directly coupled to” other elements or layers, there are no intervening elements or layers. The terms used here are only intended to describe the particular examples, and are not used as limitations of the present disclosure. As used herein, “a”, “an” and “said/the” in singular forms are intended to include the plural forms as well, unless the context clearly dictates otherwise. It should also be understood that at least one of the terms “consists of” or “comprising”, when used in this specification, identify the presence of at least one of stated features, integers, operations, elements or components, but do not exclude presence or addition of at least one of one or more other features, integers, operations, elements, components or groups. As used herein, the term “at least one of . . . ” includes any and all combinations of the associated listed items.

It should be understood that, references to “one example” or “an example” throughout this specification mean that particular features, structures, or characteristics related to the example are comprised in at least one example of the present disclosure. Therefore, “in one example” or “in an example” presented throughout this specification does not necessarily refer to the same example. Furthermore, these particular features, structures, or characteristics may be incorporated in one or more examples in any suitable manner. It is to be understood that, in various examples of the present disclosure, sequence numbers of the above processes do not indicate an execution order, and an execution order of various processes shall be determined by functionalities and intrinsic logics thereof, and shall constitute no limitation on an implementation process of the examples of the present disclosure. The above sequence numbers of the examples of the present disclosure are only for description, and do not represent advantages or disadvantages of the examples. The methods disclosed in the several method examples provided in the present disclosure can be arbitrarily combined without conflict to obtain new method examples.

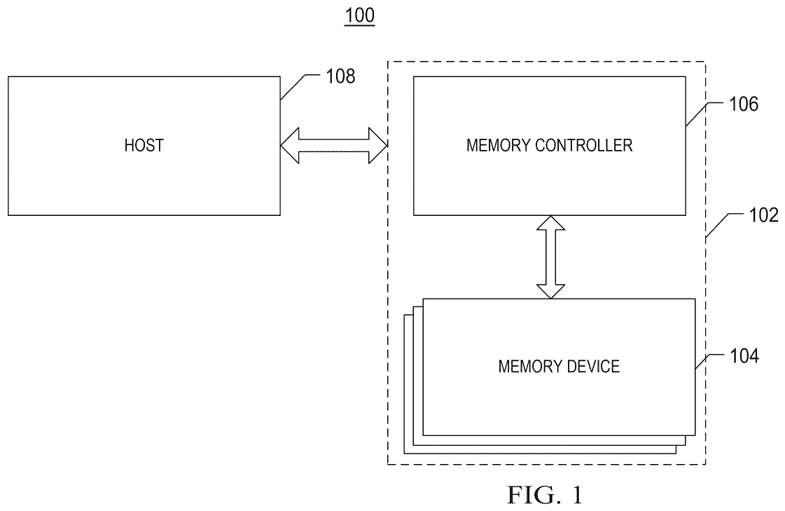

FIG. 1 illustrates a block diagram of an example system 100 having a memory device, according to some aspects of the present disclosure. System 100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 1, system 100 can include a host 108 and a memory system 102 having one or more memory devices 104 and a memory controller 106. The host 108 can be a processor of an electronic device, such as a central processing unit (CPU), or a system-on-chip (SoC), such as an application processor (AP). The host 108 can be configured to send or receive data to or from the memory device 104. The memory device 104 may include, but is not limited to, a 2D or 3D Not-And (NAND) type memory, a NOR type memory, a Ferroelectric Random Access Memory (FRAM), a Magnetic Random Access Memory (MRAM), a Phase-Change Memory (PCM), and a Resistive Random Access Memory (RRAM), etc.

The memory controller 106 is coupled to the memory device 104 and the host 108 and is configured to control the memory device 104, according to some examples. The memory controller 106 can manage the data stored in the memory device 104 and communicate with the host 108. In some examples, the memory controller 106 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some examples, the memory controller 106 is designed for operating in a high duty-cycle environment SSD or embedded multi-media-cards (eMMCs) used as data storage for mobile devices, such as smartphones, tablets, laptop computers, etc., and enterprise storage arrays.

The memory controller 106 can be configured to control operations of the memory device 104, such as read, erase, and program operations. The memory controller 106 can also be configured to manage various functions with respect to the data stored or to be stored in the memory device 104 including, but not limited to bad-block management, garbage collection, logical-to-physical address conversion, wear leveling, etc. In some examples, the memory controller 106 is further configured to process error correction codes (ECC) with respect to the data read from or written to the memory device 104. Any other suitable functions may be performed by the memory controller 106 as well, for example, formatting the memory device 104. The memory controller 106 can communicate with an external device (e.g., the host 108) according to a particular communication protocol. For example, the memory controller 106 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

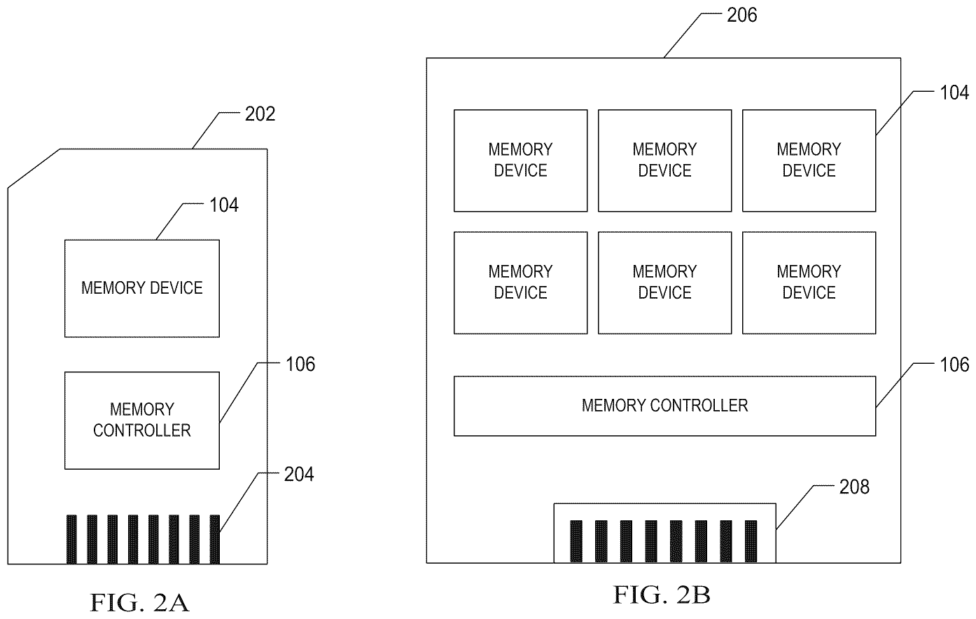

The memory controller 106 and one or more memory devices 104 can be integrated into various types of storage devices, for example, be included in the same package, such as a universal Flash storage (UFS) package or an eMMC package. That is, the memory system 102 can be implemented and packaged into different types of end electronic products. In one example as shown in FIG. 2A, the memory controller 106 and a single memory device 104 may be integrated into a memory card 202. The memory card 202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. The memory card 202 can further include a memory card connector 204 coupling the memory card 202 with a host (e.g., the host 108 in FIG. 1). In another example as shown in FIG. 2B, the memory controller 106 and multiple memory devices 104 may be integrated into an SSD 206. The SSD 206 can further include an SSD connector 208 coupling the SSD 206 with a host (e.g., the host 108 in FIG. 1). In some examples, at least one of the storage capacity or the operation speed of the SSD 206 is greater than those of the memory card 202.

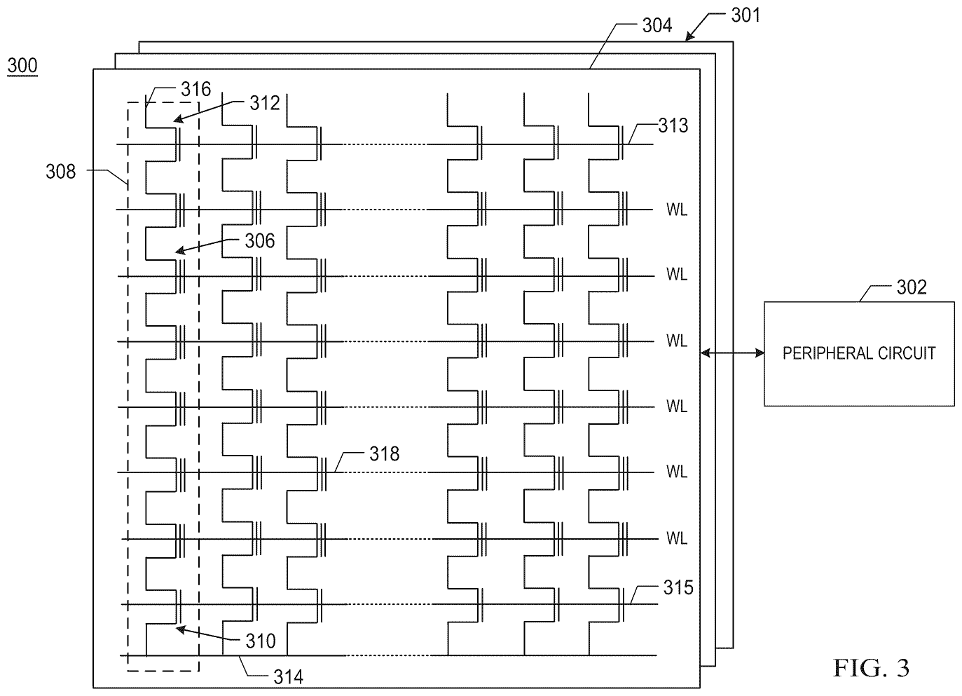

The memory device 104 in the examples of the present disclosure is explained and illustrated using the Not-And (NAND) type memory as an example, and the memory device 104 in the examples of the present disclosure may include other memories. FIG. 3 illustrates a schematic circuit diagram of an example memory device 300 including a peripheral circuit, according to some aspects of the present disclosure. The memory device 300 can be an example of the memory device 104 in FIG. 1. The memory device 300 can include a memory cell array 301 and a peripheral circuit 302 coupled to the memory cell array 301. The memory cell array 301 is illustrated as an example of a three-dimensional NAND type memory cell array, in which memory cells 306 are provided in the form of an array of NAND memory strings 308 each extending vertically above a substrate (not shown). In some examples, each NAND memory string 308 includes a plurality of or multiple memory cells 306 coupled in series and stacked vertically. Each memory cell 306 can hold a continuous, analog value, such as an electrical voltage or charge, that depends on the number of electrons trapped within a region of the memory cells 306. Each memory cell 306 can be either a floating gate type of memory cell including a floating-gate transistor or a charge trap type of memory cell including a charge-trap transistor.

In some examples, each memory cell 306 is a single-level cell (SLC) that has two possible memory states and thus, can store one bit of data. For example, the first memory state “0” can correspond to a first range of voltages, and the second memory state “1” can correspond to a second range of voltages. In some examples, each memory cell 306 is a multi-level cell (MLC) that is capable of storing more than a single bit of data in more than four memory states. For example, the MLC can store two bits per cell, three bits per cell (also known as Trinary-Level cell (TLC)), or four bits per cell (also known as a Quad-Level cell (QLC)). Each MLC can be programmed to assume a range of possible nominal storage values. In one example, if each MLC stores two bits of data, then the MLC can be programmed to write one of three possible nominal storage values to the cell, and a fourth nominal storage value except for the three nominal storage values can be used to indicate the erased state.

As shown in FIG. 3, each NAND memory string 308 can include a bottom selective gate (BSG) 310 at its source end and a top selective gate (TSG) 312 at its drain end. BSG 310 and TSG 312 can be configured to activate selected NAND memory strings 308 during read and program operations. In some examples, the sources of NAND memory strings 308 in the same memory block 304 are coupled through the same source line (SL) 314, e.g., a common SL. For example, all NAND memory strings 308 in the same memory block 304 have an array common source (ACS), according to some examples. TSG 312 of each NAND memory string 308 is coupled to a respective bit line (BL) 316 from which data can be read or written via an output bus (not shown), according to some examples. In some examples, each NAND memory string 308 is configured to be selected or deselected by at least one of: applying a select voltage (e.g., above the threshold voltage of the transistor having TSG 312) or a deselect voltage (e.g., 0 V) to respective TSG 312 through one or more TSG lines 313 or applying a select voltage (e.g., above the threshold voltage of the transistor having BSG 310) or a deselect voltage (e.g., 0 V) to respective BSG 310 through one or more BSG lines 315.

As shown in FIG. 3, the NAND memory strings 308 can be organized into multiple memory blocks 304, each of which can have a common source line 314, e.g., coupled to the ground. In some examples, each memory block 304 is the basic data unit for erase operations, e.g., all memory cells 306 on the same memory block 304 are erased at the same time. To erase memory cells 306 in a selected memory block, source lines 314 coupled to the selected memory block as well as unselected memory blocks in the same plane as the selected memory block can be biased with an erase voltage (Vers), such as a high positive voltage (e.g., 20 V or more). It is understood that in some examples, the erase operation may be performed at a half-memory block level, a quarter-memory block level, or a level having any suitable number of memory blocks or any suitable fractions of a memory block. Memory cells 306 of adjacent NAND memory strings 308 can be coupled through word lines 318 that select which row of memory cells 306 is affected by read and program operations.

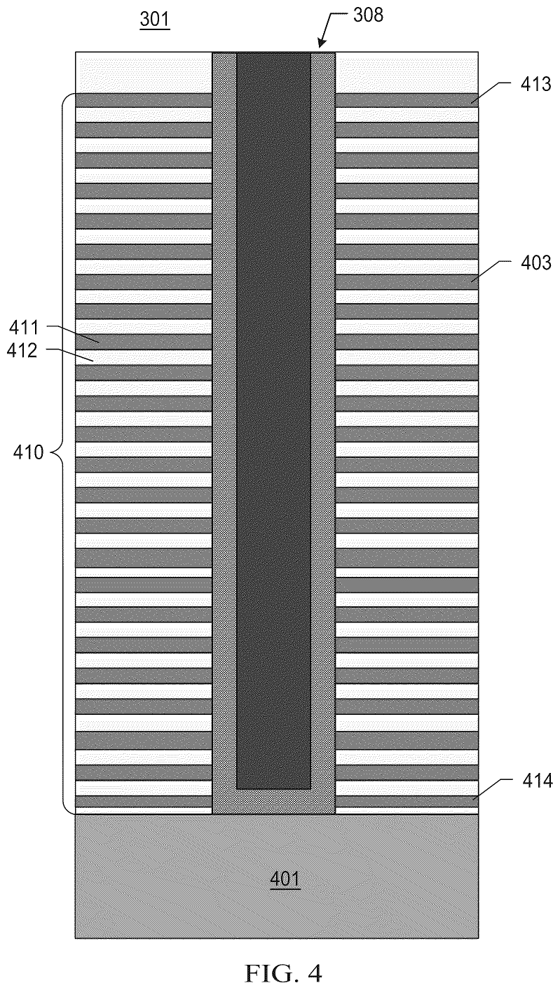

FIG. 4 shows a schematic cross-sectional view of an example memory cell array 301 including NAND memory strings 308 in accordance with aspects of the present disclosure. As shown in FIG. 4, the NAND memory cell array 301 may include a stacked structure 410, which includes a plurality of or multiple gate layers 411 and a plurality of or multiple insulating layers 412 alternately stacked in sequence, and a memory string penetrating vertically through the gate layers 411 and the insulating layers 412. The gate layer 411 and the insulating layer 412 can be stacked alternately, and two adjacent gate layers 411 are separated by an insulating layer 412. The number of pairs of gate layers 411 and insulating layers 412 in the stacked structure 410 may determine the number of memory cells included in the memory cell array 301.

The constituent material of the gate layer 411 may include a conductive material. The conductive material may include but is not limited to tungsten (W), cobalt (Co), Copper (Cu), aluminum (Al), polysilicon, doped silicon, silicide, or any combination thereof. In some examples, each gate layer 411 may include a metal layer, e.g., a tungsten layer. In some examples, each gate layer 411 includes a doped polysilicon layer. Each gate layer 411 may include a control gate surrounding the memory cell. The gate layer 411 at the top of the stacked structure 410 may extend laterally as a top selective gate line, the gate layer 411 at the bottom of the stacked structure 410 may extend laterally as a bottom selective gate line, and the gate layer 411 extending laterally between the top selective gate line and the bottom selective gate line may be used as a word line layer.

In some examples, the stacked structure 410 may be disposed on a substrate 401. The substrate 401 may include silicon (e.g., monocrystalline silicon), silicon germanium (SiGe), gallium arsenide (GaAs), germanium (Ge), silicon-on-insulator (SOI), germanium-on-insulator (GOI), or any other suitable material.

In some examples, the NAND memory string 308 includes a channel structure extending vertically through the stacked structure 410. In some examples, the channel structure includes a channel hole filled with semiconductor material(s) (e.g., as a semiconductor channel) and dielectric material(s) (e.g., as a memory film). In some examples, the semiconductor channel includes silicon, e.g., polysilicon. In some examples, the memory film is a composite dielectric layer including a tunneling layer, a storage layer (also referred to as a “charge trap/storage layer”), and a blocking layer. The channel structure may have a cylindrical shape (e.g., a pillar shape). According to some examples, the semiconductor channel, the tunneling layer, the storage layer and the blocking layer are radially arranged in this order from the center of the pillar toward the outer surface of the pillar. The tunneling layer may include silicon oxide, silicon oxynitride, or any combination thereof. The storage layer may include silicon nitride, silicon oxynitride, or any combination thereof. The blocking layer may include silicon oxide, silicon oxynitride, a high dielectric constant (high-k) dielectric, or any combination thereof. In one example, the memory film may include a composite layer of silicon oxide/silicon oxynitride/silicon oxide (ONO).

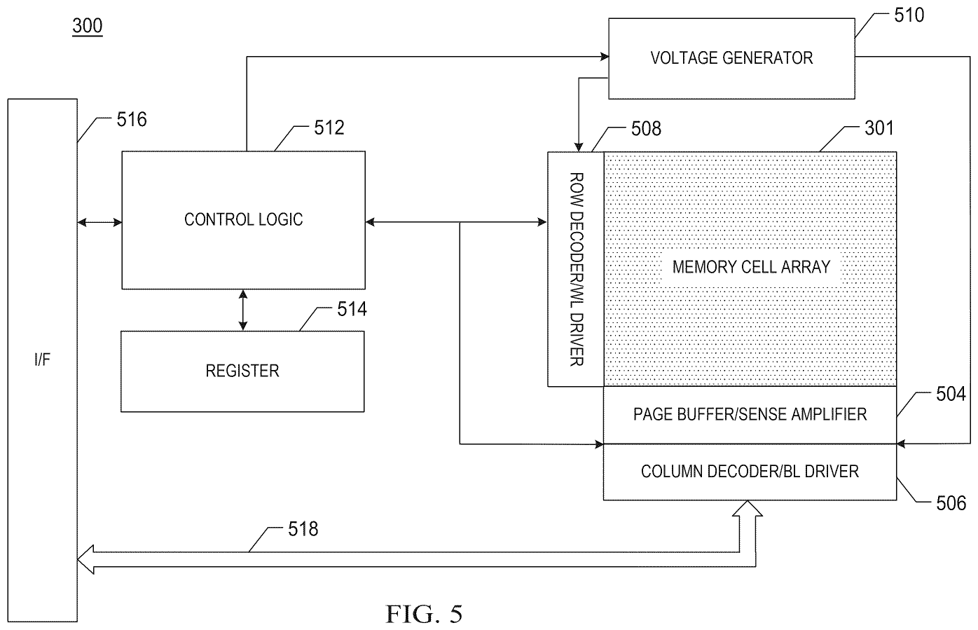

Referring back to FIG. 3, the peripheral circuit 302 can be coupled to the memory cell array 301 through bit lines 316, word lines 318, source lines 314, BSG lines 315, and TSG lines 313. The peripheral circuit 302 can include any suitable analog, digital, and mixed-signal circuits for facilitating the operations of the memory cell array 301 by applying and sensing at least one of voltage signals or current signals to and from each target memory cell 306 through bit lines 316, word lines 318, source lines 314, BSG lines 315, and TSG lines 313. The peripheral circuit 302 can include various types of peripheral circuits formed using metal-oxide-semiconductor (MOS) technologies. For example, FIG. 5 illustrates some example peripheral circuits, the peripheral circuit 302 including a page buffer/sense amplifier 504, a column decoder/bit line driver 506, a row decoder/word line driver 508, a voltage generator 510, control logic 512, registers 514, an interface 516, and a data bus 518. It is understood that in some examples, additional peripheral circuits not shown in FIG. 5 may be included as well.

The page buffer/sense amplifier 504 can be configured to read and program (write) data from and to the memory cell array 301 according to the control signals from the control logic 512. In one example, the page buffer/sense amplifier 504 may store program data (write data) to be programmed into the memory cell array 301. In another example, the page buffer/sense amplifier 504 may perform program verify operations to ensure that the data has been properly programmed into memory cells 306 coupled to selected word lines 318. In still another example, the page buffer/sense amplifier 504 may also sense the low power signals from the bit line 316 that represent data bits stored in the memory cells 306 and amplify the small voltage swing to recognizable logic levels in a read operation. The column decoder/bit line driver 506 can be configured to be controlled by the control logic 512 and select one or more NAND memory strings 308 by applying bit line voltages generated from the voltage generator 510.

The row decoder/word line driver 508 can be configured to be controlled by the control logic 512 and select/deselect memory blocks 304 of the memory cell array 301 and select/deselect word lines 318 of memory blocks 304. The row decoder/word line driver 508 can be further configured to drive word lines 318 using word line voltages generated from the voltage generator 510. In some examples, the row decoder/word line driver 508 can also select/deselect and drive BSG lines 315 and TSG lines 313 as well. As described below in detail, the row decoder/word line driver 508 is configured to perform program operations on the memory cells 306 coupled to the selected word line(s) 318. The voltage generator 510 can be configured to be controlled by the control logic 512 and generate the word line voltages (e.g., read voltage, program voltage, pass voltage, channel boost voltage, verification voltage, etc.), bit line voltages, and source line voltages to be supplied to the memory cell array 301.

The control logic 512 may be coupled to each peripheral circuit described above and configured to control the operation of each peripheral circuit. Registers 514 can be coupled to the control logic 512 and include status registers, command registers, and address registers for storing status information, command operation codes (OP codes), and command addresses for controlling the operations of each peripheral circuit. The interface 516 may be coupled to the control logic 512 and act as a control buffer to buffer and relay control commands received from a host (not shown) to the control logic 512, and to buffer and relay status information received from the control logic 512 to the host. The interface 516 may further be coupled to the column decoder/bit line driver 506 via the data bus 518 and act as a data I/O interface and data buffer to buffer and relay data to or from the memory cell array 301.

In some examples, the memory cell of the NAND memory may be classified into single-level memory cells (one-bit memory cells), double-level memory cells (two-bit memory cells), triple-level memory cells (three-bit memory cells), quad-level memory cells (four-bit memory cells), and penta-level memory cells (five-bit memory cells) according to a storage density. However, regardless of the single-level memory cell or the multi-level memory cell, the read operation thereof may be performed on a per-page basis. In an example, during the read operation, a read voltage is applied to the word line (e.g., the selected word line) coupled with the selected page in the memory device 104, and when the read voltage reaches a threshold voltage of a plurality of or multiple memory cells coupled with the selected word line, or a count of memory cells each having a threshold voltage not reached by the read voltage is within a tolerance range, the read operation of the entire page is ended. The memory cell may be an M-bit memory cell which has 2^{M} memory states comprising an erased state, wherein M bits of stored data are read through 2^{M}−1 levels of read voltages. In an example, e.g., a first-level read voltage is between threshold voltages of the erased state and a first data state, when the first-level read voltage is applied to the word line, memory cells in the erased state are turned on, memory cells in the first memory state are turned off, and the erased state and the first memory state are distinguished from each other and read out.

It is to be noted that during a process of the read operation, a memory cell with a target threshold voltage not reached by the read voltage is labeled as an error bit. In order to prevent the read error, an Error Correction Code (ECC) is introduced, so that all error bits in the read operation can be corrected when an error bit count is less than or equal to a maximum count of fail bits that can be corrected by the error correction code. As such, the data may be read properly.

In some examples, the host 108 sends a read command (or a read instruction, a read request) to the memory controller 106 according to a current user command requirement. The memory controller 106 transmits a read control command comprising information such as a logical address-physical address mapping table to the memory device 104 via the interface 516, to control the memory device 104 to perform the read operation on the memory cell corresponding to a respective physical address. The memory device 104 then sends read data to the memory controller 106 via the interface 516. The memory controller 106 feeds back the data to the host 108 via interfaces such as PCIe or SATA. In an example, the memory controller 106 sends the read control command to the control logic of the memory device via the interface 516, and the control logic applies a related operation voltage to the selected word line or bit line according to a related physical address, so as to perform the read operation on the corresponding memory cell. The control logic may control the voltage generator to generate, according to a related read voltage mapping table, the related operation voltage, which is decoded by the row decoder and then applied to the word line of the respective address, or decoded by the column decoder and then applied to the bit line of the respective address.

In some other examples, a read error occurs when the memory device 104 reads the respective memory cell under the control of the memory controller 106. At this time, the memory controller 106 (or an error correction module in the memory controller 106) controls the memory device 104 to perform error correction in response to a read operation failure, wherein an error correction mode may include ECC error correction.

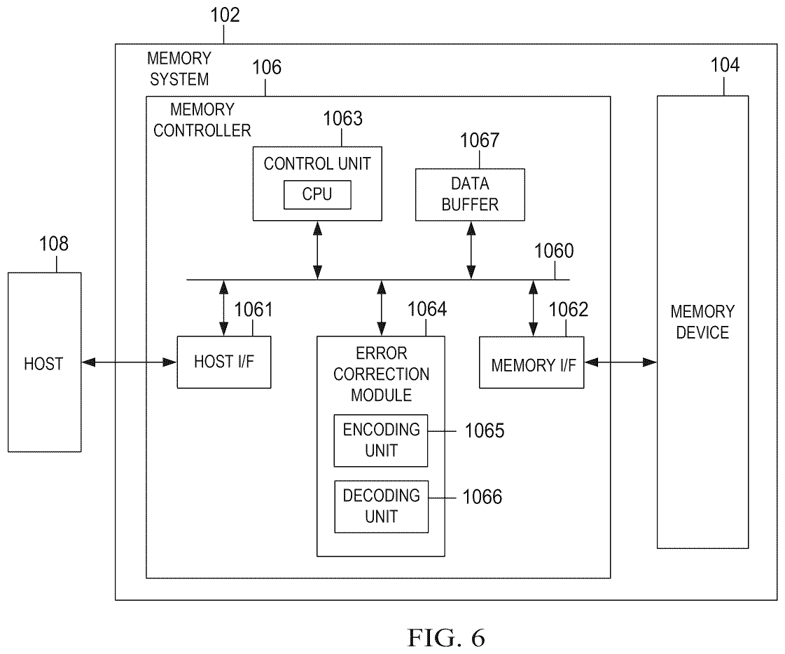

FIG. 6 provides a block diagram of applying the memory controller 106 to the memory system 102. Referring to FIG. 6, the memory system 102 comprises: the memory controller 106 and the memory device 104, wherein the memory controller 106 and the memory device 104 may be coupled in any suitable pattern. In the examples of the present disclosure, the memory controller 106 comprises a host I/F 1061, a memory I/F 1062, a control unit 1063, the error correction (ECC) module 1064, the data buffer 1067, and an internal bus 1060, wherein the error correction module 1064 comprises an encoding unit 1065 and the decoding unit 1066. The host I/F 1061 outputs a command and user data (write data) etc. received from the host 108 to the internal bus 1060, and sends user data (read data) read from the memory device 104 and a response from the control unit 1063, etc. to the host 108.

The memory I/F controls processing of writing user data etc. to the memory device 104 and reading user data etc. from the memory device 104 based on an instruction of the control unit 1063. The control unit 1063 overall controls the memory system 102, and comprises, for example, a central processing unit (CPU), or a micro-processing unit (MPU), etc. The control unit 1063 performs control according to a command in the case of receiving the command from the host 108 via the host I/F 1061. For example, the control unit 1063 instructs the memory I/F 1062 to write the user data and parity check data to the memory device 104 according to the command from the host 108. Furthermore, according to the command from the host 108, the control unit 1063 instructs the memory I/F 1062 that the memory device 104 performs the program operation on the memory cells, updates the physical address-logical address mapping table after completing the program operation, and gives feedback to the data buffer 1067 via the memory I/F 1062 for storage. Alternatively, according to the command from the host 108, the control unit 1063 instructs the memory I/F 1062 that the memory device 104 reads the user data and the parity check data from the memory device 104.

The error correction module 1064 comprises the encoding unit 1065 and the decoding unit 1066, and the encoding unit 1065 encodes the user data with a predetermined size written to the same page to generate the parity check data, wherein encoding may be performing based on program data to generate the parity check data. The parity check data is written to a page to which the user data as the encoding basis has been written, and the decoding unit 1066 uses the parity check data for decoding. The data buffer 1067 temporarily stores the user data received from the host 108 before storing it to the memory device 104, and temporarily stores the data read from the memory device 104 before sending it to the host 108.

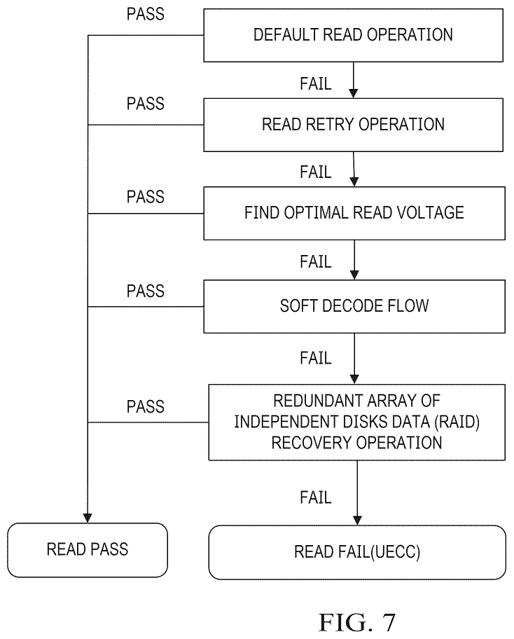

According to some aspects of examples of the present disclosure, FIG. 7 is a schematic flow diagram illustrating example operations of the memory system 102 for dealing with a read operation failure. Referring to FIG. 7, when the memory controller 106 controls the memory device 104 to perform the read operation, a default read operation is first performed on the memory cell of a respective physical address. After the default read fails, an access to a read retry table (RRT) is performed to acquire a voltage offset value, and the voltage offset value and a default read voltage are summed to obtain a read retry voltage for a read retry operation. The default read voltage is a value calibrated in factory tests of the memory device, and is stored in the memory device for calling by the memory controller or the peripheral circuit of the memory device. The read retry operation and the default read operation may employ a hard bit decode (HB decode). After the read retry fails, an operation of finding an optimal read level, which may also be referred to as a valley voltage search operation, is performed. A positive or negative offset is performed based on the default read voltage or a read voltage for the current read failure, whereby an optimal read voltage is obtained by increasing or decreasing the voltage for performing a read operation on the memory cell. The read operation with the redetermined optimal read voltage may employ the hard bit decode or soft bit decode (SB decode), or employ the soft bit decode after the hard bit decode fails. After a read operation with the optimal read voltage fails, a soft decode flow, which is also referred to as a soft decision operation, is performed, which may comprise a hard bit read (HB read). The hard read data employs the hard bit decode or updates a log likelihood rate (LLR) table independent of an LDPC algorithm. The soft decode flow may also comprise a soft bit read (SB read), wherein the soft bit read data employs the soft bit decode. After the soft decode flow fails, a redundant array of independent disks (RAID) data recovery operation is performed, or a Redundant Array of Independent NAND (RAIN) technology is enabled. After the RAID or RAIN operation fails, the ECC error correction operation stops, a read failure occurs due to inability of the error correction operation, and the memory controller 106 sends a read failure or UECC signal to the host 108.

In an example, RAID may be a disk-level data recovery technology, wherein one memory device 104 may act as one disk, a plurality of or multiple disks constitute a disk array, and when a data read error occurs in one or more disks, error data may be recovered through check data and data in a disk in which no error occurs. The check data may be generated during a disk write period according to written data. The RAIN may be referred to as NAND-level RAID. For the memory device 104 comprising a NAND memory array, the check data may be generated during a program period based on program data of a plurality of or multiple data blocks, and stored in an over-provisioning (OP) area of the memory device 104, wherein one data block may comprise data of one memory cell or of a plurality of or multiple memory cells on one word line. When a data read error occurs in one or more data blocks, error data may be recovered according to the check data and data with no error.

The error correction module 1064 (e.g., an ECC module) in the memory controller 106 may control the memory device 104 to perform error correction operations such as the read retry operation, the operation of finding the optimal read voltage, the soft decode flow, and the RAID operation. The control command is sent by the memory controller 106 to the memory device 104 via the interface 516. The memory device 104 feeds back read information to the memory controller 106 via the interface 516. It is to be noted that the performance of subsequent operations may be stopped after any one of the read retry operation, the soft decode flow, and the RAID operation succeeds.

In some examples, the soft decode flow may be understood as performing data re-decoding through a decoding unit 1066 (e.g., a soft decoder) in the memory controller 106 and performing the read operation again according to re-decoded data. The operations such as RAID and RAIN and the like may be understood as implementing data mirroring through secondary encoding, to rebuild stored data and parity check data thereof, wherein re-encoding of a redundant array for the memory data is typically performed in a data buffer 1067 of the memory controller 106.

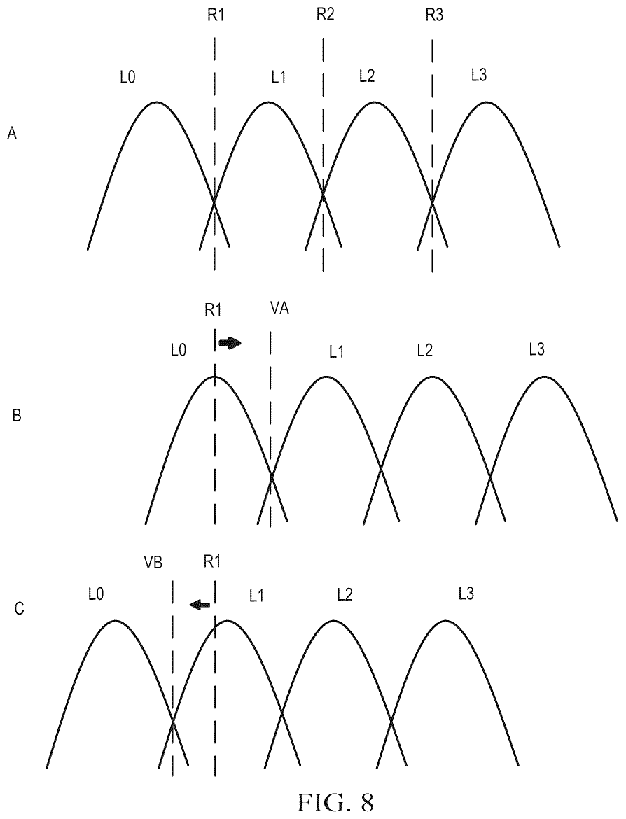

In some examples, referring to FIG. 8, the memory cells may be configured as MLC memory cells having 4 data states, wherein L0 may be an erased state, and L1 to L3 are non-erased states, e.g., program states. A memory cell may comprise more data states, which is not limited in the examples. As shown in Part A of FIG. 8, the data states L0 to L3 may be distinguished from one another using 3 read voltages, e.g., read voltages R1, R2, and R3, which are located between peaks of threshold voltage distributions, and the optimal read voltages may be located at or near valleys. In an example, during the read operation performed on the MLC memory cells, a memory cell having a threshold voltage less than R1 is in the state L0, a memory cell having a threshold voltage between R1 and R2 is in the state L1, and a memory cell having a threshold voltage greater than R3 is in the state L3. The threshold voltage distribution corresponding to each data state may be a normal distribution or an approximately normal distribution. The horizontal axis of the threshold voltage distribution may correspond to the voltage value, and the vertical axis of the threshold voltage distribution may correspond to the memory cell count. Take adjacent states L0 and L1 as an example, the optimal read voltage R1 for distinguishing the state L0 from the state L1 may be located at a valley between a threshold voltage distribution corresponding to the state L0 and a threshold voltage distribution corresponding to the state L1. The read voltages R1, R2, and R3 located at valleys may be default read voltages, which are optimal read voltages with respect to the threshold voltage distributions in Part A. The default read voltages may be determined in a factory test period according to threshold voltage distributions after a program operation, and stored in a certain memory area of the memory device 104 for being called by the memory controller 106 or the peripheral circuit of the memory device 104. The threshold voltage distributions shown in Part B of FIG. 8 have a positive offset relative to those in Part A. At this time, a valley voltage is also located at VA after the positive offsetting, and the default read voltage R1 in Part A may no longer be located at a valley of the threshold voltages after the offsetting in Part B, e.g., at this time, R1 is not an optimal read voltage. In order to obtain the optimal read voltage, R1 may be positively offset in order to be close or equal to VA, thereby finding the optimal read voltage for reading the data properly. The threshold voltage distributions shown in Part C of FIG. 8 have a negative offset relative to those in Part A. At this time, a valley voltage is also located at VB after the negative offsetting, and the default read voltage R1 in Part A may no longer be located at a valley of the threshold voltages after the offsetting in Part C, e.g., at this time, R1 is not an optimal read voltage. In order to obtain the optimal read voltage, R1 may be negatively offset in order to be close or equal to VB. In an example, the threshold voltage of a memory cell may be offset due to factors such as temperature, read disturbance, etc.

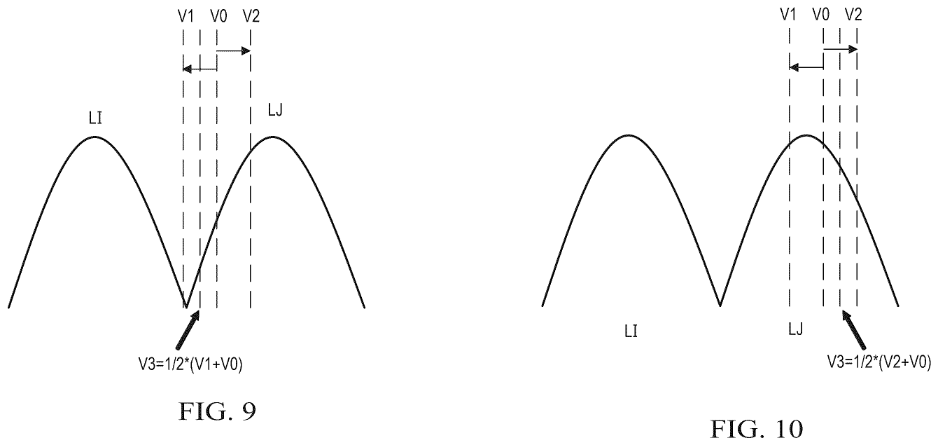

In some examples, referring to FIG. 9, take any two adjacent data states Li and Lj among a plurality of or multiple data states as an example, during searching for the optimal read voltage between the threshold voltage distribution corresponding to the state Li and the threshold voltage distribution corresponding to the state Lj, an offset stepwise search may be performed based on V0, wherein V0 may be the default read voltage between the threshold voltage distribution corresponding to the state Li and the threshold voltage distribution corresponding to the state Lj. The default read voltage may be a read voltage determined based on threshold voltage distributions of the respective data states after the program operation. During searching for the optimal read voltage between the threshold voltage distribution corresponding to the state Li and the threshold voltage distribution corresponding to the state Lj, the memory controller 106 may perform a positive or negative offset based on V0 according to some offset algorithms, e.g., V0+ΔV, wherein ΔV may be a positive or negative value. The read operation is then performed on the memory cell using V0+ΔV, and whether a read result is correctable is determined by analyzing whether the result falls within a determined error range. In an example, the offset algorithm may be executed by the control unit 1063 in the memory controller 106, and analyzing the result may comprise comparing the read results obtained using a plurality of or multiple read voltages, and a count of flipped bits between the read results.

In FIG. 9, V0 can be positively offset to V2, V0 can be negatively offset to V1, or V0 can be negatively offset to V3, wherein V3 may be calculated as being equal to a mean of V1 and V0 according to the offset algorithm. V0 is between a peak of the threshold voltage distribution corresponding to the state Li and a peak of the threshold voltage distribution corresponding to the state Lj, and the optimal read voltage may be obtained by offsetting V0 toward a valley between the two threshold voltage distributions. At the beginning of the offsetting, it can be tried to offset V0 positively or negatively according to the associated offset algorithm, perform the read operation with the read voltage after being offset, and the read result is analyzed to determine whether the read voltage after being offset is correctable. It may be determined according to the analysis result that V0, after making a negative offset, is closest to correct voltage for reading data.

In FIG. 10, due to an excessively large negative offset of the threshold voltage, V0 is located on the right of the peak of the threshold voltage distribution corresponding to the state Lj, and a voltage corresponding to the maximum memory cell count on the threshold voltage distribution corresponding to the state Lj is less than V0. V0 can be positively offset to V2, V0 can be negatively offset to V1, or V0 can be positively offset to V3, wherein V3 may be calculated as being equal to a mean of V2 and V0 according to the offset algorithm. Using V0 as a reference, FIG. 10 illustrates two valleys, one being located between the threshold voltage distribution corresponding to the state Li and the threshold voltage distribution corresponding to the state Lj, and the other being located on the right of the threshold voltage distribution corresponding to the state Lj. At this time, V0 may be offset toward the valley on the right of the threshold voltage distribution corresponding to the state Lj to obtain V3 and V2. For example, a peak of a threshold voltage distribution corresponding to a state Lj+1 may also exist. That is, V0 was originally the read voltage located between the threshold voltage distribution corresponding to the state Li and the threshold voltage distribution corresponding to the state Lj, and is then located between the threshold voltage distribution corresponding to the Lj state and the threshold voltage distribution corresponding to the state Lj+1 due to a significant offset. Accordingly, it is possible that V0 is taken as a read voltage between the threshold voltage distribution corresponding to the state Lj and the threshold voltage distribution corresponding to the state Lj+1, and is offset toward a valley between the threshold voltage distribution corresponding to the state Lj and the threshold voltage distribution corresponding to the state Lj+1, causing an error in an offset direction and failing to obtain the optimal read voltage. For example, when V0 is negatively offset after a positive offset of V0 fails may increase operation time for finding the optimal read voltage, thereby reducing an operation rate of the memory system 102. In an example, the offset of the read voltage V0 illustrated in FIG. 9 and FIG. 10 may be applied to the operation of finding the optimal read voltage following a failure of the read retry operation shown in FIG. 7. The default read voltage or a read voltage of a current read operation which fails is positively or negatively offset, whereby the voltage is increased or decreased to obtain the optimal read voltage for performing the read operation on the memory cells, e.g., re-determining the optimal read voltage for performing the read operation.

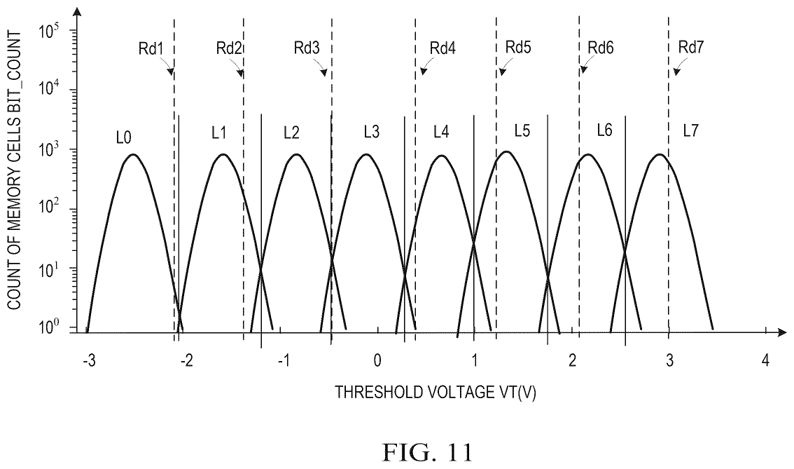

In some examples, FIG. 11 illustrates an example diagram of a read voltage offset for TLC type memory cells, wherein the horizontal axis may correspond to the threshold voltage and the vertical axis may correspond to the memory cell count (bit-count). The TLC memory cells have 8 target states L0 to L7 comprising an erased state, wherein seven periods of read voltages Rd1 to Rd7 are provided to distinguish between respective data states, wherein a memory cell having a threshold voltage less than Rd1 is in the state L0, a memory cell having a threshold voltage between Rd1 and Rd2 is in the state L1, and a memory cell having a threshold voltage greater than Rd7 is in a state L7. A read voltage (or default read voltage) corresponding to the state L1 may be Rd1, and a read voltage corresponding to the state L7 may be Rd7. Alternatively, Rd1 is a read voltage between the threshold voltage distribution corresponding to the state L0 and the threshold voltage distribution corresponding to the state L1, and Rd7 is a read voltage between a threshold voltage distribution corresponding to a state L6 and a threshold voltage distribution corresponding to the state L7. An optimal location of the read voltage is at a valley between peaks of threshold voltage distributions of adjacent data states, for example, an optimal location of Rd1 is at a valley between the threshold voltage distribution corresponding to the state L0 and the threshold voltage distribution corresponding to the state L1; an optimal location of Rd5 is at a valley between a threshold voltage distribution corresponding to a state L4 and a threshold voltage distribution corresponding to a state L5, e.g., 1 V or approximately 1 V; and an optimal location of R7 is at a valley between the threshold voltage distribution corresponding to the state L6 and the threshold voltage distribution corresponding to the state L7.

When there is no offset of the threshold voltages, each read voltage may be located at a valley and be a valley voltage, or may be located near the valley voltage. At this time, the read voltages may be stored in the memory device as default read voltages for being called by the memory device during the read operation to distinguish between the data states. In FIG. 11, due to impacts of the factors such as temperature and read disturbance, the threshold voltage corresponding to each data state is offset, and the default read voltage that was originally located at the valley is no longer at a valley of the threshold voltage distributions after the offset, so that the data states cannot be correctly distinguished from one another in the case of a large offset, leading to a read error. Respective data states have different offset directions relative to the threshold voltages. For example, a valley voltage between the threshold voltage distribution corresponding to the state L0 and the threshold voltage distribution corresponding to the state Li has a positive offset relative to Rd1, in which case Rd1 may be positively offset to obtain the optimal read voltage at the valley; a valley voltage between two threshold voltage distributions corresponding to the states L1 and L2 has a positive offset relative to Rd2, in which case Rd2 may be positively offset to obtain the optimal read voltage; a valley voltage between two threshold voltage distributions corresponding to the states L2 and L3 has little offset or substantially has no offset relative to Rd3, in which case Rd3 may be the optimal read voltage; a valley voltage between two threshold voltage distributions corresponding to the states L3 and L4 has a negative offset relative to Rd4, in which case Rd4 may be negatively offset to obtain the optimal read voltage; a valley voltage between two threshold voltage distributions corresponding to the states L4 and L5 has a negative offset relative to Rd5, in which case Rd5 may be negatively offset to obtain the optimal read voltage; a valley voltage between two threshold voltage distributions corresponding to the states L5 and L6 has a negative offset relative to Rd6, in which case Rd6 may be negatively offset to obtain the optimal read voltage; and a valley voltage between two threshold voltage distributions corresponding to the states L6 and L7 has a negative offset relative to Rd7, in which case Rd7 may be negatively offset to obtain the optimal read voltage. Rd7 is greater than a peak voltage of the threshold voltage distribution corresponding to the state L7. Rd7 may be positively offset towards a valley on the right of the threshold voltage distribution of the state L7 during the offset of Rd7, e.g., a computation of the offset algorithm within a voltage range of 3 V to 4 V results in a failure to obtain the optimal read voltage. For example, when Rd7 is negatively offset after a positive offset of Rd7 fails may increase operation time for finding the optimal read voltage, thereby reducing an operation rate. In view of above, according to some aspects of examples of the present disclosure, the offset direction of the read voltage or default read voltage to be offset is determined prior to performing the offset algorithm, and the voltage is increased or decreased in conjunction with the determined offset direction to obtain the optimal read voltage, thereby improving the operation rate of the memory system 102.

According to some aspects of examples of the present disclosure, FIG. 1 provides the memory system 102, comprising: the memory device 104 and the memory controller 106 coupled with the memory device. The memory device 104 comprises a plurality of or multiple memory cells, wherein each of the plurality of or multiple memory cells is configured to be in one of a plurality of or multiple data states. The memory controller 106 is configured to: control the memory device 104 to perform a single level read (SLR) operation; in response to a first count of memory cells each having a threshold voltage less than a default read voltage being less than a first threshold, determine that an optimal read voltage has a positive offset relative to the default read voltage; and in response to the first count of memory cells each having a threshold voltage less than the default read voltage being greater than a second threshold, determine that the optimal read voltage has a negative offset relative to the default read voltage, wherein the first threshold is less than the second threshold, wherein a first intermediate voltage is a voltage corresponding to the maximum memory cell count in a first threshold voltage distribution corresponding to memory cells in a first data state among the plurality of or multiple memory cells; a second intermediate voltage is a voltage corresponding to the maximum memory cell count in a second threshold voltage distribution corresponding to memory cells in a second data state among the plurality of or multiple memory cells; the first data state and the second data state are two adjacent data states among the plurality of or multiple data states; the first threshold is a count of memory cells each having a threshold voltage less than a first voltage in all threshold voltage distributions of the plurality of or multiple data states; the second threshold is a count of memory cells each having a threshold voltage less than a second voltage in all the threshold voltage distributions of the plurality of or multiple data states; the first voltage is less than the second voltage, and the first voltage and the second voltage are both between the first intermediate voltage and the second intermediate voltage.

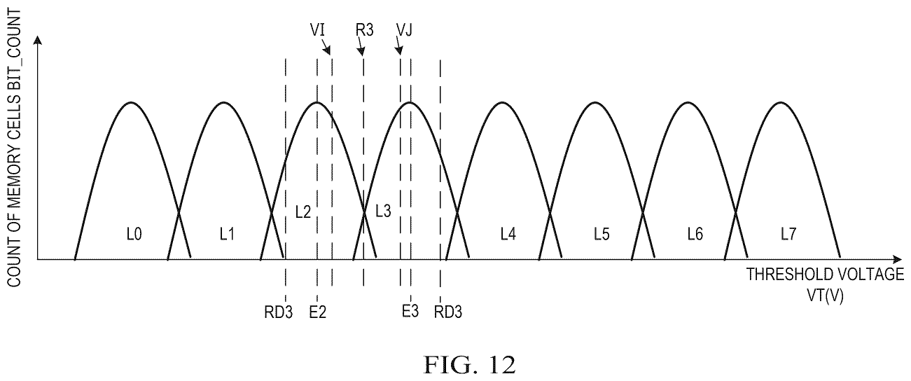

With reference to FIG. 12, the examples of the present disclosure are explained and illustrated using the TLC memory cells, such as an offset of the read voltage Rd3 between L2 and L3, as an example. Rd3 may be a default read voltage calibrated in the factory test period, or a default read voltage determined according to a threshold voltage after a program operation, or any read voltage to be offset to find an optimal read voltage, such as a first read voltage, a second read voltage, or a read try voltage. With reference to FIG. 12, the first data state of the examples of the present disclosure may be the state L2, and the first threshold voltage distribution is the threshold voltage distribution corresponding to the state L2, wherein the vertical axis represents the memory cell count, and the horizontal axis represents the voltage value. The first threshold voltage distribution may be a normal distribution or an approximately normal distribution, and the first intermediate voltage, denoted by E2, is a peak voltage of the threshold voltage distribution corresponding to L2, e.g., a value corresponding to the voltage denoted by E2 on a curve of the threshold voltage distribution is the maximum value. The second data state may be the state L3, and the second threshold voltage distribution is the threshold voltage distribution curve of the state L3. The second intermediate voltage is denoted by E3, and E3 is a peak voltage on the threshold voltage distribution of the state L3. R3 is the valley voltage between the threshold voltage distribution corresponding to the state L2 and the threshold voltage distribution corresponding to the state L3, and the optimal read voltage after offset may be at the valley voltage R3 or close to the valley voltage R3.

Rd3 is offset to be located between E2 and E3 and then the voltage value is increased or decreased based on Rd3 to find the optimal read voltage, thereby increasing the operation rate of the memory system 102. A voltage interval may be selected from the voltage interval E2 to E3, such as Vi to Vj, wherein Vi is denoted as the first voltage and Vj is denoted as the second voltage. The first voltage may be a voltage on the first threshold voltage distribution corresponding to the state L2, and the second voltage may be a voltage on the second threshold voltage distribution corresponding to the state L3, wherein E2≤Vi<Vj≤E3. Rd3 is offset to be located between Vi and Vj, and then the voltage value is increased or decreased based on Rd3 to find the optimal read voltage. By reducing the length of the interval for the voltage offset, the time for finding the optimal read voltage is reduced, and the operation rate is improved. A read voltage between any adjacent data states can be offset, e.g., the read voltage Rd1 between the threshold voltage distribution corresponding to the state L0 and the threshold voltage distribution corresponding to the state L1. At this time, the first intermediate voltage is E1, and the second intermediate voltage is E2, wherein E1≤Vi<Vj≤E2, and the other read voltages, such as Rd2, Rd4 to Rd7, are not repeated here.

In some examples, a memory cell count corresponding to each data state is determined after a program operation. In a program period of the memory cells, a write operation can be performed randomly based on data. During programming of the memory cells of a minimum program unit (or a minimum program area) in the memory device 104, the memory cells of the minimum program unit are all memory cells on one word line or memory cells on a partial area of one word line where read and write operations can be performed independently. Counts of all the data states are equal or approximately equal within a certain error range, the memory cell of which a target data state is the erased state will not be programmed, a threshold voltage distribution of each data state is a normal distribution, and areas of threshold voltage distributions of all the data states are equal or approximately equal within a certain error range. Take the MLC in FIG. 8 as an example, a total count of the memory cells in the minimum program unit is Z, the MLC has a total of four data states, and the memory cell count corresponding to each data state may be configured as Z/4. If the memory cell is configured as the TLC, the memory cell count corresponding to each data state may be Z/8, and if the memory cell is configured as the QLC, the memory cell count corresponding to each data state may be Z/16.

In FIG. 12, using the peak voltage E2 as a reference, for the threshold voltage distributions of all the data states, a count of memory cells each having a threshold voltage less than E2 is determined and may be 2.5Z/8, or close to 2.5Z/8; and using the peak voltage E3 as a reference, for the threshold voltage distributions of all the data states, a count of memory cells each having a threshold voltage less than E3 is determined and may be 3.5Z/8, or close to 3.5Z/8. As such, the memory cell counts may be used to represent threshold voltages with no offset according to the threshold voltage distribution, and a count of memory cells which have been read may be compared with a calibrated memory cell count to represent an offset direction and offset degree of a read voltage relative to the read voltage before offset.

In some examples, the memory controller 106 is further configured to: send a first operation command to the memory device 104, wherein the memory device 104 is configured to: enable a single level read operation mode in response to the first operation command.

In the case where the memory controller 106 sends the first operation command to the memory device 104 and the memory device 104 enables a single level read operation after receiving the first operation command, address information of a memory cell on which the read operation need to be performed may be sent along with the first operation command, and the first operation command may comprise the address information. The single level read mode comprises: reading at least one bit of stored data stored in the memory cell through one period of read voltage, configuring the memory cell as an SLC and reading it with a read voltage, and analyzing bit information read from the memory cell. The memory cell having a threshold voltage less than the read voltage is read as 1, and the memory cell having a threshold voltage greater than the read voltage is read as 0. The single level read operation does not require the application of all the read voltages prior to analyzing the read results, and does not require particular distinguishing of all the data states. Taking Rd3 as an example, after application of Rd3, a count of memory cells each having a threshold voltage less than Rd3 is the first count, e.g., the count of bit information read as “1”, wherein the first count may be obtained by the peripheral circuit of the memory device 104 according to the read results and sent to the memory controller 106, or the first count may be obtained by the control unit of the memory controller 106 according to the read results of the memory device 104 and the offset direction for obtaining the optimal read voltage can be determined. When the memory device 104 performs a non-single level read operation, e.g., when a read mode for distinguishing between all the data states is required, the memory device 104 receives the read command (which may be a second operation command), and applies the read voltages Rd1 to Rd7 to the memory cells at respective addresses to distinguish between the states L0 to L7. The read voltages may not be applied in the order of Rd1 to Rd7.

In some examples, when the first voltage Vi is equal to the first intermediate voltage E2, the first threshold may be 2.5Z/8; when the second voltage Vj is equal to the second intermediate voltage E3, the second threshold may be 3.5Z/8. In response to the first count being less than the first threshold, it is determined that the optimal read voltage may be obtained by offsetting Rd3 positively, and in response to the first count being greater than the second threshold, it is determined that the optimal read voltage may be obtained by offsetting Rd3 negatively. Rd3 is offset as being located between E2 and E3 according to the first count, and the offset may be stopped when the first count read based on Rd3 is greater than the first threshold and less than the second threshold. The voltage value is increased or decreased based on the Rd3 after the offset and the determined offset direction to find the optimal read voltage, wherein the optimal read voltage may be the valley voltage R3, or close to R3. A range for finding the optimal read voltage based on the offset of Rd3 may be set as from E2 to E3, so as to increase a rate of obtaining the optimal read voltage and increase the accuracy of determining the optimal read voltage.

In some examples, when E1<Vi<Vj<E2, 2.5Z/8<first threshold<second threshold<3.5Z/8, wherein the first threshold and the second threshold may be values calibrated in the factory test and stored in a certain memory area of the memory device 104 for being called by the memory controller 106. After the single level read operation is performed on the memory cells on respective addresses using Rd3, the first count is acquired; when the first count is less than the first threshold, it is determined that the optimal read voltage may be obtained by offsetting Rd3 positively, and when the first count is greater than the second threshold, it is determined that the optimal read voltage may be obtained by offsetting Rd3 negatively. Rd3 may be offset as being located between Vi and Vj according to the first count, and then the voltage value for reading is increased or decreased based on the Rd3 after offset and the determined offset direction, and the read result is matched with a correct read result in conjunction with a bit flip algorithm etc., to find the optimal read voltage. A range for finding the optimal read voltage based on the offset of Rd3 may be set as from Vi to Vj, so as to increase the rate of obtaining the optimal read voltage and increase the accuracy of determining the optimal read voltage. When the first count is less than the first threshold, the larger the difference between the first count and the first threshold, the larger the offset value required to offset Rd3 positively; and when the first count is larger than the second threshold, the larger the difference between the first count and the second threshold, the larger the offset value required to offset Rd3 negatively.

In some examples, during searching for the optimal read voltage based on Rd3, the memory controller 106 may increase or decrease the voltage value of Rd3 to obtain the Rd3 after offset, and send a value of the Rd3 after offset to the control logic of the memory device 104. The control logic controls the voltage generator to generate a corresponding read voltage and a pass voltage Vpass for applying to the word line of the respective address to perform the read operation on the memory cells, and determines whether a read result is correctable, so as to judge whether the threshold voltage is at a valley. A method of finding the optimal read voltage may include, but is not limited to: determining the offset direction of Rd3 according to a relationship of the first count with respect to the first threshold and the second threshold; performing the single level read operation using Rd3+ΔV, wherein ΔV is a positive value for positive offset, and is a negative value for negative offset; and in response to a count of memory cells each having a threshold voltage less than Rd3+ΔV being equal to a third threshold that may be equal to or close to 3Z/8 within a certain error range, determining that Rd3+ΔV is the optimal read voltage at this time.

In the examples of the present disclosure, the memory controller 106 is configured to: control the memory device 104 to perform the single level read operation; in response to the first count of memory cells each having a threshold voltage less than the default read voltage being less than the first threshold, determine that the optimal read voltage has a positive offset relative to the default read voltage; and in response to the first count of memory cells each having a threshold voltage less than the default read voltage being greater than the second threshold, determine that the optimal read voltage has a negative offset relative to the default read voltage. The offset direction may be determined prior to increasing or decreasing the default read voltage or another read voltage to be offset, so that the voltage value is increased or decreased based on the offset direction to find the optimal read voltage. The optimal read voltage may then be located between peaks of current threshold voltage distributions of two adjacent data states, and the optimal read voltage may be located at a valley between the current threshold voltage distributions of two adjacent data states, reducing the operation time for finding the optimal read voltage, increasing the accuracy of the found optimal read voltage, and thereby increasing the operation rate of the memory system 102.

In some examples, the first voltage is a voltage in the first threshold voltage distribution; and the second voltage is a voltage in the second threshold voltage distribution.

With reference to FIG. 12, taking the first voltage Vi and the second voltage Vj as an example, when the first voltage Vi is on the first threshold voltage distribution corresponding to the state L2 and the second voltage Vj is on the threshold voltage distribution corresponding to the state L3, the valley voltage R3 may be located between Vi and Vj, a voltage interval for finding the optimal read voltage based on the offset of Rd3 may comprise R3, which is favorable to fast and accurate determining of the optimal read voltage at the valley.

In some examples, the memory controller 106 is further configured to: stop offsetting the default read voltage in response to one of the following conditions being met: the first count is greater than the first threshold and less than the second threshold; the first count is equal to the first threshold; and the first count is equal to the second threshold. When Rd3 is offset to a voltage interval [Vi, Vj], Rd3 may be equal to Vi or Rd3 can be equal to Vj, and the offsetting for determining the default read voltage is stopped. At this time, a value range for finding the optimal read voltage based on Rd3 may be set in the interval [Vi, Vj], and the optimal read voltage may be found subsequently based on increasing or decreasing the voltage value of Rd3.

In some examples, the memory device 104 is further configured to: acquire the first count according to a result of a read operation, wherein the memory controller 106 is configured to: compare the first count acquired by the memory device 104 with the first threshold; and/or compare the first count acquired by the memory device 104 with the second threshold; and according to a result of the comparison, determine that the optimal read voltage has a positive offset relative to the default read voltage, or the optimal read voltage has a negative offset relative to the default read voltage.

The control logic of the memory device 104 receives a read voltage (e.g., a default read voltage after being offset or another voltage) sent by the memory controller 106, controls the voltage generator to generate a corresponding read voltage and a pass voltage Vpass etc., and applies the corresponding voltage to the relevant word line for reading according to the address information. The memory cell having a threshold voltage less than the applied read voltage is turned on when the read voltage is applied and may be read as “1”; and the memory cell having a threshold voltage greater than the applied read voltage is off when the read voltage is applied and may be read as “0”. The first count may be obtained through a count of “1”, wherein the count may be determined by the control logic and sent to the memory controller 106, or the memory controller 106 may also acquire the count from the memory controller 106 per se. The memory controller 106 compares the first count with the first threshold and the second threshold, and determines the offset direction for obtaining the optimal read voltage and an offset value, and may generate a new read voltage and send it to the memory device 104 to perform the read operation.

In some examples, the first count may be calculated by the memory controller 106, and the memory controller 106 is further configured to: acquire a result of a read operation performed by the memory device 104 on the plurality of or multiple memory cells; and acquire the first count according to the result of the read operation. The memory controller 106 accesses the memory device 104 to acquire information of read “1” and/or “0”, or the memory controller 106 receives the information of “1” and/or “0” sent by the memory device 104, and calculates the first count based on the read information.

In some examples, the memory controller 106 is further configured to: before determining an offset direction relative to the default read voltage for obtaining the optimal read voltage, control the memory device to perform a read operation using the default read voltage; and in response to a read failure of the memory device, determine that the optimal read voltage has a positive offset or a negative offset relative to the default read voltage. Referring to FIG. 11, taking the read voltages Rd1 and Rd3 as an example, the valley voltage between the two threshold voltage distributions corresponding to the state L0 and the state L1 has little offset relative to Rd1, and the valley voltage between the two threshold voltage distributions corresponding to the state L2 and the state L3 has little offset relative to Rd3, in which case data can be read correctly during the read operation so that an offset for finding the optimal read voltage may not be needed. Taking Rd7 as an example, the valley voltage between the two threshold voltage distributions corresponding to the state L6 and the state L7 has a larger offset relative to Rd7, and when an error occurs when performing the read operation with it, the offset direction may be determined and the optimal read voltage may be found along the offset direction.

In some examples, the memory controller 106 is further configured to: determine the optimal read voltage according to the default read voltage after being offset, and control the memory device 104 to perform a read operation using the optimal read voltage; in response to first failure information of the memory device 104, perform a read retry operation for at least one time, and perform a hard bit decode operation on data obtained after the read retry operation is performed each time, wherein the first failure information is to indicate a read failure of the read operation performed using the optimal read voltage; perform a soft bit decode operation for at least one time in response to a failure of the hard bit decode operation; and perform a redundant array of independent disks (RAID) data recovery operation or Redundant Array of Independent NAND (RAIN) technology in response to a failure of the soft bit decode operation.

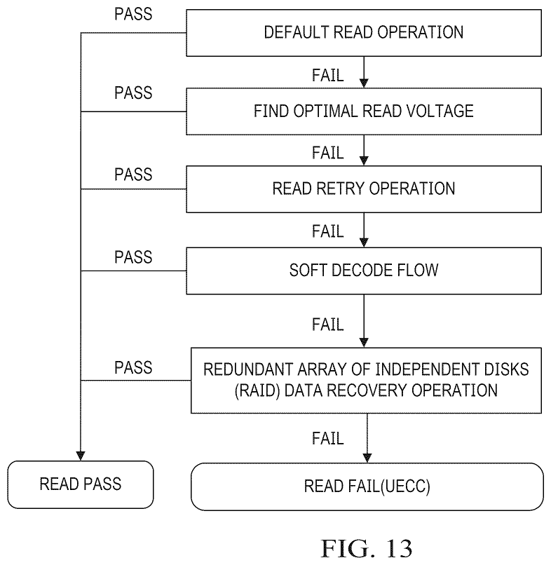

With reference to FIG. 13, after the read failure of the read operation using the default read voltage, the memory controller 106 may control the memory device 104 to perform the single level read operation using one period of default read voltage, so as to obtain the first count. The memory controller 106 determines the offset direction relative to the default read voltage for obtaining the optimal read voltage according to the first count, the first threshold, and the second threshold, increases or decreases the voltage value according to the determined offset direction to obtain the optimal read voltage, and performs the read operation using the optimal read voltage. If the read operation using the optimal read voltage fails, the read retry table is accessed to acquire the voltage offset value, and the offset value and the optimal read voltage are summed to obtain a read retry voltage for a read retry operation. After the read retry operation fails, the soft bit decode operation is performed, and after the soft bit decode fails, the RAID or RAIN operation is performed. If any one of the operations shown in FIG. 13 can read the data correctly, then the subsequent operations are stopped.

In some examples, the memory controller 106 is further configured to: control the memory device 104 to perform a read operation using the default read voltage; in response to second failure information of the memory device 104, perform a read retry operation for at least one time, and perform a hard bit decode operation on data obtained after the read retry operation is performed each time, wherein the second failure information is to indicate a read failure of the read operation performed using the default read voltage; in response to a failure of the hard bit decode operation, determine the optimal read voltage according to the offset of the default read voltage, and perform the read operation using the optimal read voltage; and perform a redundant array of independent disks (RAID) data recovery operation or RAIN in response to a read failure using the optimal read voltage.

With reference to FIG. 7, after the read retry operation using the default read voltage fails, the single level read operation is performed on the memory cells using one period of default read voltage, and the first count is acquired. The offset direction relative to the default read voltage for obtaining the optimal read voltage is determined according to the first count, the first threshold, and the second threshold, the voltage value is increased or decreased according to the determined offset direction to obtain the optimal read voltage, and the read operation is performed using the optimal read voltage. The read operation using the re-determined optimal read voltage may employ the hard bit decode or soft bit decode, or employ the soft bit decode after the hard bit decode fails. After the read failure of the read operation using the optimal read voltage, the soft decode flow, which is also referred to as the soft decision, is performed. The soft decode flow may comprise a hard bit read. The hard read data employs the hard bit decode or updates an LLR table independent of an LDPC algorithm. The soft decode flow may also comprise a soft bit read, wherein the soft bit read data employs the soft bit decode. After the soft decode flow fails, the RAID operation or RAIN operation is performed.

In some examples, the plurality of or multiple data states are read through a plurality of or multiple read voltages, the optimal read voltage determined according to the first threshold voltage distribution and the second threshold voltage distribution is a first optimal read voltage, the first optimal read voltage has an offset relative to a first default read voltage, and the memory controller 106 is configured to: determine that offset directions of at least part of other optimal read voltages relative to corresponding default read voltages are the same as an offset direction of the first optimal read voltage. Taking the seven periods of default read voltages Rd1 to Rd7 of the TLC as an example, in some specific working conditions, offset directions of the seven periods of default read voltages relative to the valley voltages after the offset may be the same; alternatively, a part of the default read voltages are positively offset relative to the valley voltages after the offset, and a part of the default read voltages are negatively offset relative to the valley voltages after the offset. For read voltages have the same offset directions, a first offset direction corresponding to one of the read voltages may be determined, and the first optimal read voltage is obtained by offsetting according to the first offset direction; and for read voltages have the same offset directions as this read voltage, the first offset direction may be applied directly to find the optimal read voltage, omitting operations such as the single level read operation and acquisition of the first count, thereby increasing the operation rate of the memory system 102.

In some examples, the plurality of or multiple read voltages are divided into a plurality of or multiple intervals, each interval comprises one read voltage or a plurality of or multiple adjacent read voltages, and the optimal read voltage in each interval has the same offset direction relative to the corresponding default read voltage, wherein the memory controller 106 is further configured to: determine that an offset direction of the optimal read voltage in another interval is different from the offset direction of the first optimal read voltage.

With reference to FIG. 11, due to the offset of the threshold voltage, the default read voltages Rd1, Rd2, and Rd3 may have negative offsets of different degrees relative to the valley voltage after the offset, and Rd1, Rd2, and Rd3 are classified into a first interval; the default read voltages Rd4, Rd5, Rd6, and Rd7 may have positive offsets of different degrees relative to the valley voltage after the offset, and may be classified into a second interval. In some specific working conditions, a read voltage corresponding to a higher data state has a larger offset, e.g., Rd7. Rd7 corresponding to the program state L7 may be selected as a voltage for the single level read operation. The first count of memory cells each having a threshold voltage less than Rd7 is acquired, the first count being greater than the second threshold, and Rd7 is negatively offset to acquire the optimal read voltage. The other read voltages Rd4, Rd5, and Rd6 in the second interval may be determined to be negatively offset to acquire the optimal read voltage, omitting operations such as the single level read operation and acquisition of the first count. The read voltages in the first interval may be determined to be positively offset to acquire the optimal read voltage, omitting operations such as the single level read operation and acquisition of the first count, thereby increasing the operation rate of the memory system 102.

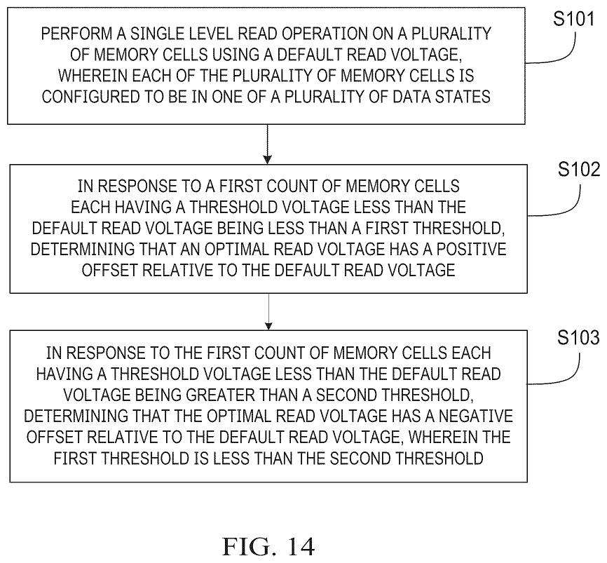

According to some aspects of examples of the present disclosure, FIG. 14 provides a method of controlling the memory system 102, comprising: performing a single level read operation on a plurality of or multiple memory cells using a default read voltage, wherein each of the plurality of or multiple memory cells is configured to be in one of a plurality of or multiple data states; in response to a first count of memory cells each having a threshold voltage less than the default read voltage being less than a first threshold, determining that an optimal read voltage has a positive offset relative to the default read voltage; and in response to the first count of memory cells each having a threshold voltage less than the default read voltage being greater than a second threshold, determining that the optimal read voltage has a negative offset relative to the default read voltage, wherein the first threshold is less than the second threshold; wherein a first intermediate voltage is a voltage corresponding to the maximum memory cell count in a first threshold voltage distribution corresponding to memory cells in a first data state among the plurality of or multiple memory cells; a second intermediate voltage is a voltage corresponding to the maximum memory cell count in a second threshold voltage distribution corresponding to memory cells in a second data state among the plurality of or multiple memory cells; the first data state and the second data state are two adjacent data states among the plurality of or multiple data states; the first threshold is a count of memory cells each having a threshold voltage less than a first voltage in threshold voltage distributions of the plurality of or multiple data states; the second threshold is a count of memory cells each having a threshold voltage less than a second voltage in the threshold voltage distributions of the plurality of or multiple data states; the first voltage is less than the second voltage, and the first voltage and the second voltage are both between the first intermediate voltage and the second intermediate voltage.

In some examples, the method comprises: sending, by a memory controller 106, a first operation command to a memory device 104; and enabling, by the memory device 104, a single level read operation mode in response to the first operation command.

In some examples, the first voltage is a voltage in the first threshold voltage distribution, and the second voltage is a voltage in the second threshold voltage distribution.

In some examples, the method further comprises: stopping offsetting the default read voltage in response to one of the following conditions being met: the first count is greater than the first threshold and less than the second threshold; the first count is equal to the first threshold; and the first count is equal to the second threshold.

In some examples, the method further comprises: acquiring the first count according to a result of a read operation.

In some examples, the method further comprises: before determining an offset direction relative to the default read voltage for obtaining the optimal read voltage, performing a read operation using the default read voltage; and in response to a read failure, determining that the optimal read voltage has a positive offset or a negative offset relative to the default read voltage.

In some examples, the method further comprises: determining the optimal read voltage according to the default read voltage after being offset, and controlling the memory device 104 to perform a read operation using the optimal read voltage; in response to first failure information, performing a read retry operation for at least one time, and performing a hard bit decode operation on data obtained after the read retry operation is performed each time, wherein the first failure information is to indicate a read failure of the read operation performed using the read voltage; performing a soft bit decode operation for at least one time in response to a failure of the hard bit decode operation; and performing a redundant array of independent disks data recovery operation in response to a failure of the soft bit decode operation.

In some examples, the method further comprises: performing a read operation using the default read voltage; in response to second failure information, performing a read retry operation for at least one time, and performing a hard bit decode operation on data obtained after the read retry operation is performed each time, wherein the second failure information is to indicate a read failure of the read operation performed using the default read voltage; in response to a failure of the hard bit decode operation, determining the optimal read voltage according to the offset of the default read voltage, and performing the read operation using the optimal read voltage; and performing a redundant array of independent disks data recovery operation in response to a read failure using the optimal read voltage.

In some examples, the plurality of or multiple data states are read through a plurality of or multiple read voltages, the optimal read voltage determined according to the first threshold voltage distribution and the second threshold voltage distribution is a first optimal read voltage, the first optimal read voltage has an offset relative to a first default read voltage, and the method further comprises: determining that offset directions of at least part of other optimal read voltages relative to corresponding default read voltages are the same as an offset direction of the first optimal read voltage.

In some examples, the plurality of or multiple read voltages are divided into a plurality of or multiple intervals, each interval comprises one read voltage or a plurality of or multiple adjacent read voltages, and the optimal read voltage in each interval has the same offset direction relative to the corresponding default read voltage, wherein the method further comprises: determining that an offset direction of the optimal read voltage in another interval is different from the offset direction of the first optimal read voltage.

According to some aspects of examples of the present disclosure, there is provided a readable storage medium storing a computer program which, when executed, implements the method.

The memory device 104 may comprise a NAND memory, the memory cell of the NAND memory may either comprise a floating gate memory cell that includes a floating gate transistor, or a charge trapping memory cell that includes a charge trapping transistor.

The storage medium may be memories such as Ferromagnetic Random Access Memory (FRAM), Magnetic Random Access Memory (MRAM), Read Only Memory (ROM), or Programmable Read-Only Memory (PROM), Erasable Programmable Read-Only Memory (EPROM), Electrically Erasable Programmable Read-Only Memory (EEPROM), Flash Memory, magnetic surface memory, optical disc, or Compact Disc Read-Only Memory (CD-ROM); alternatively, it may be various devices including one of the above memory devices 104 or any combination thereof.

In some examples, executable instructions may in the form of a program, software, software module, script, or code, written in any form of programming language, including compiled or interpreted languages, or declarative or procedural languages, and may be deployed in any form, including deployed as a stand-alone program or deployed as a module, component, subroutine, or other means suitable for use in a computing environment.

As an example, executable instructions may, but do not necessarily correspond to, files in a file system and may be stored as part of a file holding other programs or data, for example, stored in one or more scripts in a Hyper Text Markup Language (HTML) document, stored in a single file that is specific to the program in question, or, stored in multiple collaborative files (for example, files that store one or more modules, subroutines, or portions of code).

As an example, the executable instruction may be deployed on an electronic apparatus for execution, or on a plurality of or multiple electronic apparatuses at one site for execution, or distributed on a plurality of or multiple electronic apparatuses interconnected through a communication network at a plurality of or multiple sites for execution.

The above descriptions are merely examples of the present disclosure, and the protection scope of the present disclosure is not limited to these. Any variation or replacement that may be readily figured out by those skilled in the art within the technical scope disclosed by the present disclosure shall fall within the protection scope of the present disclosure.

What is claimed is:

1. A memory system, comprising:
a memory device comprising memory cells, wherein each of the memory cells is configured to be in one of data states; and
a memory controller coupled with the memory device and configured to:
control the memory device to perform a single level read operation;
in response to a first count of memory cells each having a threshold voltage less than a default read voltage being less than a first threshold, determine that an optimal read voltage has a positive offset relative to the default read voltage; and
in response to the first count of memory cells each having a threshold voltage less than the default read voltage being greater than a second threshold, determine that the optimal read voltage has a negative offset relative to the default read voltage, wherein the first threshold is less than the second threshold,
wherein a first intermediate voltage is a voltage corresponding to the maximum memory cell count in a first threshold voltage distribution corresponding to memory cells in a first data state among the memory cells; a second intermediate voltage is a voltage corresponding to the maximum memory cell count in a second threshold voltage distribution corresponding to memory cells in a second data state among the memory cells; the first data state and the second data state are two adjacent data states among the data states; the first threshold is a count of memory cells each having a threshold voltage less than a first voltage in threshold voltage distributions of the data states; the second threshold is a count of memory cells each having a threshold voltage less than a second voltage in the threshold voltage distributions of the data states; the first voltage is less than the second voltage, and the first voltage and the second voltage are both between the first intermediate voltage and the second intermediate voltage.

2. The memory system of claim 1, wherein the memory controller is further configured to:
send a first operation command to the memory device,
wherein the memory device is configured to: enable a single level read operation mode in response to the first operation command.

3. The memory system of claim 1, wherein the first voltage is a voltage in the first threshold voltage distribution, and the second voltage is a voltage in the second threshold voltage distribution.

4. The memory system of claim 1, wherein the memory controller is further configured to:
stop offsetting the default read voltage in response to one of the following conditions being met:
the first count is greater than the first threshold and less than the second threshold;
the first count is equal to the first threshold; and
the first count is equal to the second threshold.

5. The memory system of claim 1, wherein the memory device is further configured to:
acquire the first count according to a result of a read operation,
wherein the memory controller is configured to:
compare the first count acquired by the memory device with the first threshold or the second threshold; and
according to a result of the comparison, determine that the optimal read voltage has a positive offset relative to the default read voltage, or the optimal read voltage has a negative offset relative to the default read voltage.

6. The memory system of claim 1, wherein the memory controller is further configured to:
acquire a result of a read operation performed by the memory device on the memory cells; and
acquire the first count according to the result of the read operation.

7. The memory system of claim 1, wherein the memory controller is further configured to:
before determining an offset direction of the optimal read voltage relative to the default read voltage, control the memory device to perform a read operation using the default read voltage; and
in response to a read failure of the memory device, determine that the optimal read voltage has a positive offset or a negative offset relative to the default read voltage.

8. The memory system of claim 1, wherein the memory controller is further configured to:
determine the optimal read voltage according to the default read voltage after being offset, and control the memory device to perform a read operation using the optimal read voltage;
in response to first failure information of the memory device, perform a read retry operation for at least one time, and perform a hard bit decode operation on data obtained after the read retry operation is performed each time, wherein the first failure information is to indicate a read failure of the read operation performed using the optimal read voltage;
perform a soft bit decode operation for at least one time in response to a failure of the hard bit decode operation; and
perform a redundant array of independent disks (RAID) data recovery operation in response to a failure of the soft bit decode operation.

9. The memory system of claim 1, wherein the memory controller is further configured to:
control the memory device to perform a read operation using the default read voltage;
in response to second failure information of the memory device, perform a read retry operation for at least one time, and perform a hard bit decode operation on data obtained after the read retry operation is performed each time, wherein the second failure information is to indicate a read failure of the read operation performed using the default read voltage;
in response to a failure of the hard bit decode operation, determine the optimal read voltage according to an offset to the default read voltage, and perform the read operation using the optimal read voltage; and
perform a redundant array of independent disks (RAID) data recovery operation in response to a read failure using the optimal read voltage.

10. The memory system of claim 1, wherein the data states are read through read voltages, the optimal read voltage determined according to the first threshold voltage distribution and the second threshold voltage distribution is a first optimal read voltage, the first optimal read voltage has an offset relative to a first default read voltage, and the memory controller is configured to:
determine that offset directions of at least part of other optimal read voltages relative to corresponding default read voltages are the same as an offset direction of the first optimal read voltage.

11. The memory system of claim 10, wherein the read voltages are divided into intervals, each interval comprises one read voltage or adjacent read voltages, and the optimal read voltage for each interval has the same offset direction relative to the corresponding default read voltage,
wherein the memory controller is further configured to:
determine that an offset direction of the optimal read voltage in another interval is different from the offset direction of the first optimal read voltage.

12. A method of controlling a memory system, comprising:
performing a single level read operation on memory cells using a default read voltage, wherein each of the memory cells is configured to be in one of data states;
in response to a first count of memory cells each having a threshold voltage less than the default read voltage being less than a first threshold, determining that an optimal read voltage has a positive offset relative to the default read voltage; and
in response to the first count of memory cells each having a threshold voltage less than the default read voltage being greater than a second threshold, determining that the optimal read voltage has a negative offset relative to the default read voltage, wherein the first threshold is less than the second threshold,
wherein a first intermediate voltage is a voltage corresponding to the maximum memory cell count in a first threshold voltage distribution corresponding to memory cells in a first data state among the memory cells; a second intermediate voltage is a voltage corresponding to the maximum memory cell count in a second threshold voltage distribution corresponding to memory cells in a second data state among the memory cells; the first data state and the second data state are two adjacent data states among the data states; the first threshold is a count of memory cells each having a threshold voltage less than a first voltage in threshold voltage distributions of the data states; the second threshold is a count of memory cells each having a threshold voltage less than a second voltage in the threshold voltage distributions of the data states; the first voltage is less than the second voltage, and the first voltage and the second voltage are both between the first intermediate voltage and the second intermediate voltage.

13. The method of claim 12, comprising:
sending, by a memory controller, a first operation command to a memory device; and
enabling, by the memory device, a single level read operation mode in response to the first operation command.

14. The method of claim 12, wherein the first voltage is a voltage in the first threshold voltage distribution, and the second voltage is a voltage in the second threshold voltage distribution.

15. The method of claim 12, further comprising:
stopping offsetting the default read voltage in response to one of the following conditions being met:
the first count is greater than the first threshold and less than the second threshold;
the first count is equal to the first threshold; and
the first count is equal to the second threshold.

16. The method of claim 12, further comprising:
acquiring the first count according to a result of a read operation.

17. The method of claim 12, further comprising:
before determining an offset direction of the optimal read voltage relative to the default read voltage, performing a read operation using the default read voltage; and
in response to a read failure, determining that the optimal read voltage has a positive offset or a negative offset relative to the default read voltage.

18. The method of claim 12, further comprising:
determining the optimal read voltage according to the default read voltage after being offset, and performing a read operation using the optimal read voltage;
in response to first failure information, performing a read retry operation for at least one time, and performing a hard bit decode operation on data obtained after the read retry operation is performed each time, wherein the first failure information is to indicate a read failure of the read operation performed using the optimal read voltage;
performing a soft bit decode operation for at least one time in response to a failure of the hard bit decode operation; and
performing a redundant array of independent disks (RAID) data recovery operation in response to a failure of the soft bit decode operation.

19. The method of claim 12, further comprising:
performing a read operation using the default read voltage;
in response to second failure information, performing a read retry operation for at least one time, and performing a hard bit decode operation on data obtained after the read retry operation is performed each time, wherein the second failure information is to indicate a read failure of the read operation performed using the default read voltage;
in response to a failure of the hard bit decode operation, determining the optimal read voltage according to an offset to the default read voltage, and performing the read operation using the optimal read voltage; and
performing a redundant array of independent disks (RAID) data recovery operation in response to a read failure using the optimal read voltage.

20. A readable storage medium storing a computer program which, when executed, implements a method of controlling a memory system, comprising:
performing a single level read operation on memory cells using a default read voltage, wherein each of the memory cells is configured to be in one of data states;
in response to a first count of memory cells each having a threshold voltage less than the default read voltage being less than a first threshold, determining that an optimal read voltage has a positive offset relative to the default read voltage; and
in response to the first count of memory cells each having a threshold voltage less than the default read voltage being greater than a second threshold, determining that the optimal read voltage has a negative offset relative to the default read voltage, wherein the first threshold is less than the second threshold,
wherein a first intermediate voltage is a voltage corresponding to the maximum memory cell count in a first threshold voltage distribution corresponding to memory cells in a first data state among the memory cells; a second intermediate voltage is a voltage corresponding to the maximum memory cell count in a second threshold voltage distribution corresponding to memory cells in a second data state among the memory cells; the first data state and the second data state are two adjacent data states among the data states; the first threshold is a count of memory cells each having a threshold voltage less than a first voltage in threshold voltage distributions of the data states; the second threshold is a count of memory cells each having a threshold voltage less than a second voltage in the threshold voltage distributions of the data states; the first voltage is less than the second voltage, and the first voltage and the second voltage are both between the first intermediate voltage and the second intermediate voltage.
